(19) United States
(12) Patent Application Publication
(10) Pub. No.: US 2024/0352051 A1
(43) Pub. Date: Oct. 24, 2024

(54) MULTI-NUCLEAR TIN COMPOUNDS AND RELATED METHODS

(71) Applicant: ENTEGRIS, INC., Billerica, MA (US)

(72) Inventors: David M. Ermert, Danbury, CT (US); Claudia Fafard, New Milford, CT (US); Thomas M. Cameron, Newtown, CT (US)

(21) Appl. No.: 18/641,306

(22) Filed: Apr. 19, 2024

Related U.S. Application Data
(60) Provisional application No. 63/460,663, filed on Apr. 20, 2023.

(51) Int. Cl. C07F 7/22

(52) U.S. Cl. CPC C07F 7/2284

(57) ABSTRACT

Multi-nuclear tin compounds and related methods are provided. A method comprises obtaining a mono-substituted tin (IV) amide compound; obtaining a silanol compound; and contacting the mono-substituted tin (IV) amide compound with the silanol compound to form a multi-nuclear tin compound. A composition comprises a multi-nuclear tin compound.

### CROSS-REFERENCE TO RELATED APPLICATIONS

This application claims the benefit under 35 USC 119 of U.S. Provisional Patent Application No. 63/460,663, filed Apr. 20, 2023, the disclosure of which is hereby incorporated herein by reference in its entirety.

### FIELD

The present disclosure relates to compositions comprising multi-nuclear tin compounds and related methods.

### BACKGROUND

Some precursors are useful in the manufacture of microelectronic devices. The manufacture of such devices can involve use of extreme ultraviolet (EUV) lithography to form thin films.

### SUMMARY

Some embodiments relate to a method comprising: contacting a mono-substituted tin (IV) amide compound with a silanol compound to form a mixed-ligand multi-nuclear tin compound, wherein the mono-substituted tin (IV) amide compound is a compound of the formula: RSn(NR¹₂)₃, where: R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; R¹ is independently a hydrogen, an alkyl, a cycloalkyl, or an aryl, or each R¹ is bonded to each other to form a C₃-C₂₀ N-heterocycle; wherein the silanol compound is a compound of the formula: HOSiR²₃, where: R² is independently at least one of a hydrogen, a halide, an alkyl, an alkenyl, an alkynyl, a cycloalkyl, an aryl, an aralkyl, an alkaryl, or a haloalkyl.

Some embodiments relate to a composition comprising: a mixed-ligand multi-nuclear tin compound of the formula: [R₂Sn₂(NR¹₂)ₙ(OSiR²₃)₆₋ₙ]ₓ, where: R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; R¹ is independently a hydrogen, an alkyl, a cycloalkyl, or an aryl, or each R² is bonded to each other to form a C₃-C₂₀ N-heterocycle; R² is independently at least one of a hydrogen, a halide, an alkyl, an alkenyl, an alkynyl, a cycloalkyl, an aryl, an aralkyl, an alkaryl, or a haloalkyl; x is 1, 1.5, or 2; n is 1 to 5.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for producing a multi-nuclear tin compound, according to some embodiments.

FIG. 2 depicts a schematic sectional view of a non-limiting embodiment of an ampoule, according to some embodiments.

FIG. 3 is a thermogravimetric analysis of iPr₂Sn₂ (μ-N(CH₃)₂)(OSi(CH₃)₃)₅, according to some embodiments.

FIG. 4 is a solid-state three-dimensional structural analysis of iPr₂Sn₂ (μ-N(CH₃)₂)(OSi(CH₃)₃)₅, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₅ alkyl, a C₁-C₂ alkyl, a C₂-C₃₀ alkyl, a C₅-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₈-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof. In some embodiments, the term “alkyl” refers generally to alkyls, alkenyls, alkynyls, and/or cycloalkyls.

As used herein, the term “alkenyl” refers to a hydrocarbyl having from 1 to 30 carbon atoms and at least one carbon-carbon double bond. In some embodiments, the alkenyl comprises or is selected from the group consisting of at least one of a C₁-C₃₀ alkenyl, C₁-C₂₉ alkenyl, C₁-C₂₈ alkenyl, C₁-C₂₇ alkenyl, C₁-C₂₇ alkenyl, C₁-C₂₆ alkenyl, C₁-C₂₅ alkenyl, C₁-C₂₄ alkenyl, C₁-C₂₃ alkenyl, C₁-C₂₂ alkenyl, C₁-C₂₁ alkenyl, C₁-C₂₀ alkenyl, C₁-C₁₉ alkenyl, C₁-C₁₈ alkenyl, C₁-C₁₇ alkenyl, C₁-C₁₆ alkenyl, C₁-C₁₅ alkenyl, C₁-C₁₄ alkenyl, C₁-C₁₃ alkenyl, C₁-C₁₂ alkenyl, C₁-C₁₁ alkenyl, C₁-C₁₀ alkenyl, a C₁-C₉ alkenyl, a C₁-C₈ alkenyl, a C₁-C₇ alkenyl, a C₁-C₆ alkenyl, a C₁-C₅ alkenyl, a C₁-C₄ alkenyl, a C₁-C₃ alkenyl, a C₁-C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₅-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “alkynyl” refers to a hydrocarbyl having from 1 to 30 carbon atoms and at least one carbon-carbon triple bond. In some embodiments, the alkynyl comprises or is selected from the group consisting of at least one of a C₁-C₃₀ alkynyl, C₁-C₂₉ alkynyl, C₁-C₂₈ alkynyl, C₁-C₂₇ alkynyl, C₁-C₂₇ alkynyl, C₁-C₂₆ alkynyl, C₁-C₂₅ alkynyl, C₁-C₂₄ alkynyl, C₁-C₂₃ alkynyl, C₁-C₂₂ alkynyl, C₁-C₂₁ alkynyl, C₁-C₂₀ alkynyl, C₁-C₁₉ alkynyl, C₁-C₁₈ alkynyl, C₁-C₁₇ alkynyl, C₁-C₁₆ alkynyl, C₁-C₁₅ alkynyl, C₁-C₁₄ alkynyl, C₁-C₁₃ alkynyl, C₁-C₁₂ alkynyl, C₁-C₁₁ alkynyl, C₁-C₁₀ alkynyl, a C₁-C₉ alkynyl, a C₁-C₈ alkynyl, a C₁-C₇ alkynyl, a C₁-C₆ alkynyl, a C₁-C₅ alkynyl, a C₁-C₄ alkynyl, a C₁-C₃ alkynyl, a C₁-C₂ alkynyl, a C₂-C₃₀ alkynyl, a C₃-C₃₀ alkynyl, a C₄-C₃₀ alkynyl, a C₅-C₃₀ alkynyl, a C₆-C₃₀ alkynyl, a C₇-C₃₀ alkynyl, a C₈-C₃₀ alkynyl, a C₉-C₃₀ alkynyl, a C₁₀-C₃₀ alkynyl, a C₁₁-C₃₀ alkynyl, a C₁₂-C₃₀ alkynyl, a C₁₃-C₃₀ alkynyl, a C₁₄-C₃₀ alkynyl, a C₁₅-C₃₀ alkynyl, a C₁₆-C₃₀ alkynyl, a C₁₇-C₃₀ alkynyl, a C₁₈-C₃₀ alkynyl, a C₁₉-C₃₀ alkynyl, a C₂₀-C₃₀ alkynyl, a C₂₁-C₃₀ alkynyl, a C₂₂-C₃₀ alkynyl, a C₂₃-C₃₀ alkynyl, a C₂₄-C₃₀ alkynyl, a C₂₅-C₃₀ alkynyl, a C₂₆-C₃₀ alkynyl, a C₂₇-C₃₀ alkynyl, a C₂₈-C₃₀ alkynyl, a C₂₉-C₃₀ alkynyl, a C₂-C₁₀ alkynyl, a C₃-C₁₀ alkynyl, a C₄-C₁₀ alkynyl, a C₅-C₁₀ alkynyl, a C₆-C₁₀ alkynyl, a C₇-C₁₀ alkynyl, a C₈-C₁₀ alkynyl, a C₂-C₉ alkynyl, a C₂-C₈ alkynyl, a C₂-C₇ alkynyl, a C₂-C₆ alkynyl, a C₂-C₅ alkynyl, a C₃-C₅ alkynyl, or any combination thereof. Examples of alkynyl groups include, without limitation, at least one of ethynyl, propynyl, n-butynyl, n-pentynyl, 3-methyl-1-butynyl, n-hexynyl, methyl-pentynyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

As used herein, the term “amino” and/or “amine” refer to a functional group of formula —N(R^{a}R^{b}), wherein R^{a} and R^{b} are independently a hydrogen, an alkyl (as defined herein), or a silyl (as defined herein), or R^{a} and R^{b} are bonded to each other to form a C₃-C₂₀ N-heterocycle. In some embodiments, the amino may comprise an alkylamino or a dialkylamino. In some embodiments, the amino may comprise at least one of methylamino, dimethylamino, ethylamino, diethylamino, isopropylamino, di-isopropylamino, butylamino, sec-butylamino, tert-butylamino, di-sec-butylamino, isobutylamino, di-isobutylamino, di-tert-pentylamino, ethylmethylamino, isopropyl-n-propylamino, or any combination thereof. Examples of the alkylaminos may include, without limitation, one or more of the following: primary alkylaminos, such as, for example and without limitation, methylamino, ethylamino, n-propylamino, isopropylamino, n-butylamino, sec-butylamino, isobutylamino, t-butylamino, pentylamino, 2-aminopentane, 3-aminopentane, 1-amino-2-methylbutane, 2-amino-2-methylbutane, 3-amino-2-methylbutane, 4-amino-2-methylbutane, hexylamino, 5-amino-2-methylpentane, heptylamino, octylamino, nonylamino, decylamino, undecylamino, dodecylamino, tridecylamino, tetradecylamino, pentadecylamino, hexadecylamino, heptadecylamino, and octadecylamino; and secondary alkylaminos, such as, for example and without limitation, dimethylamino, diethylamino, dipropylamino, diisopropylamino, dibutylamino, diisobutylamino, di-sec-butylamino, di-t-butylamino, dipentylamino, dihexylamino, diheptylamino, dioctylamino, dinonylamino, didecylamino, methylethylamino, methylpropylamino, methylisopropylamino, methylbutylamino, methylisobutylamino, methyl-sec-butylamino, methyl-t-butylamino, methylamylamino, methylisoamylamino, ethylpropylamino, ethylisopropylamino, ethylbutylamino, ethylisobutylamino, ethyl-sec-butylamino, ethylamino, ethylisoamylamino, propylbutylamino, and propylisobutylamino.

As used herein, the term “alkoxy” refers to a functional group of formula —OR^{c}, wherein R^{c} is an alkyl (as defined herein), a silylalkyl, a cycloalkyl, or an aryl. In some embodiments, the alkoxy may comprise, consist of, or consist essentially of, or may selected from the group consisting of, at least one of methoxy, ethoxy, methoxy, ethoxy, n-propoxy, 1-methylethoxy (isopropoxy), n-butoxy, iso-butoxy, sec-butoxy, tert-butoxy, or any combination thereof.

As used herein, the term “silyl” refers to a functional group of formula —Si(R^{e}R^{f}R^{g}), where each of R^{e}, R^{f}, and R^{g} is independently a hydrogen or an alkyl, as defined herein. In some embodiments, the silyl is a functional group of formula —SiH₃. In some embodiments, the silyl is a functional group of formula —SiR^{e}H₂, where R^{e} is not hydrogen. In some embodiments, the silyl is a functional group of formula —SiR^{e}R^{f}H, where R^{e} and R^{f} are not hydrogen. In some embodiments, the silyl is a functional group of the formula —Si(R^{e}R^{f}R^{g}), where R^{e}, R^{f}, and R^{g} are not hydrogen. In some embodiments, the silyl is a functional group of formula —Si(CH₃)₃.

As used herein, the term “alkoxyalkyl” refers to an alkyl as defined herein, wherein at least one of the hydrogen atoms of the alkyl is replaced with an alkoxy as defined herein. In some embodiments, the term “alkoxyalkyl” refers to a functional group of formula -(alkyl) OR^{a}, wherein the alkyl is defined above and wherein the R^{a} is defined above. In some embodiments, the alkoxyalkyl is a functional group of formula —(CH₂)ₙOR^{a}, where n is 1 to 10 and R^{a} is defined above. In some embodiments, the alkoxyalkyl is a functional group of the formula —CH₂CH₂OCH₃.

As used herein, the term “aralkyl” refers to an alkyl as defined herein, wherein at least one of the hydrogen atoms of the alkyl is replaced with an aryl as defined herein. In some embodiments, the term “aralkyl” refers to a functional group of formula -(alkyl) (aryl), wherein the alkyl is defined herein and the aryl is defined herein. In some embodiments, the aralkyl is —CH₂ (C₆H₅).

As used herein, the term “aminoalkyl” refers to an alkyl as defined herein, wherein at least one of the hydrogen atoms of the alkyl is replaced with an amino as defined herein. In some embodiments, the term “aminoalkyl” refers to a functional group of formula -(alkyl) N(R^{b}R^{c}R^{d}), wherein the alkyl is defined above and wherein R^{b}, R^{c}, and R^{d} are defined above. In some embodiments, the aminoalkyl is —CH₂N(CH₃)₂. In some embodiments, the aminoalkyl is —(CH₂) 3N(CH₃)₂. In some embodiments, the aminoalkyl is aminomethyl (—CH₂NH₂). In some embodiments, the aminoalkyl is N,N-dimethylaminoethyl (—CH₂CH₂N(CH₃)₂). In some embodiments, the aminoalkyl is 3-(N-cyclopropylamino) propyl (—CH₂CH₂CH₂NH—Pr).

As used herein, the term “silylalkyl” refers to an alkyl as defined herein, wherein at least one of the hydrogen atoms of the alkyl is replaced with a silyl as defined herein. In some embodiments, the term “silylalkyl” refers to a functional group of formula -(alkyl)Si(R^{e}R^{f}R^{g}), wherein the alkyl is defined above and wherein R^{e}, R^{f}, and R^{g} are defined above. In some embodiments, the silylalky is a functional group of formula —(CH₂)ₘSi(R^{e}R^{f}R^{g}), where m is 1 to 10 and where R^{e}, R^{f}, and R^{g} are defined above. In some embodiments, the silylalkyl is a functional group of formula —CH₂Si(CH₃)₃.

As used herein, the term “haloalkyl” refers to an alkyl as defined here, wherein at least one of the hydrogen atoms of the alkyl is replaced with a halide as defined herein. In some embodiments, the haloalkyl comprises a fluoroalkyl. In some embodiments, the fluoroalkyl comprises at least one of —CH₂CF₃, —CH(CF₃)₂, —CH₂F, —CH₂CH₂F, —CF₃, —CF₂CF₃, or any combination thereof.

As used herein, the term “halide” refers to a —Cl, —Br, —I, or —F.

As used herein, the term “metal cation” refers to at least one of an alkali metal cation, an alkaline earth metal cation, a transition metal cation, a post-transition metal cation, or any combination thereof. In some embodiments, the metal cation comprises a lithium cation, a sodium cation, a potassium cation, a rubidium cation, a cesium cation, a francium cation, a beryllium cation, a magnesium cation, a calcium cation, a strontium cation, a barium cation, a radium cation, a scandium cation, a titanium cation, a vanadium cation, a chromium cation, a manganese cation, an iron cation, a cobalt cation, a nickel cation, a copper cation, a zinc cation, a yttrium cation, a zirconium cation, a niobium cation, a molybdenum cation, a technetium cation, a ruthenium cation, a rhodium cation, a palladium cation, a silver cation, a cadmium cation, a hafnium cation, a tantalum cation, a tungsten cation, a rhenium cation, an osmium cation, an iridium cation, a platinum cation, a gold cation, a mercury cation, an aluminum cation, a gallium cation, an indium cation, tin cation, a thallium cation, a lead cation, a bismuth cation, or a polonium cation. The charge(s) of the metal cations are known and, for simplicity, thus are not repeated here; however, it will be appreciated that the metal cations can have any known charge. For example, in some embodiments, the metal cation comprises Li⁺, Na⁺, K⁺, Rb⁺, Cs⁺, Mg²⁺, Ca²⁺, Sr²⁺, Ba²⁺, Zn²⁺, Sn²⁺, or Sn⁴⁺. In some embodiments, the metal cation is Sn²⁺. In some embodiments, the metal cation is Sn⁴⁺.

Some embodiments relate to precursors and related methods. At least some of these embodiments relate to precursors useful in the fabrication of microelectronic devices, including semiconductor devices, and the like. For example, the precursors can be used to form silicon-containing films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

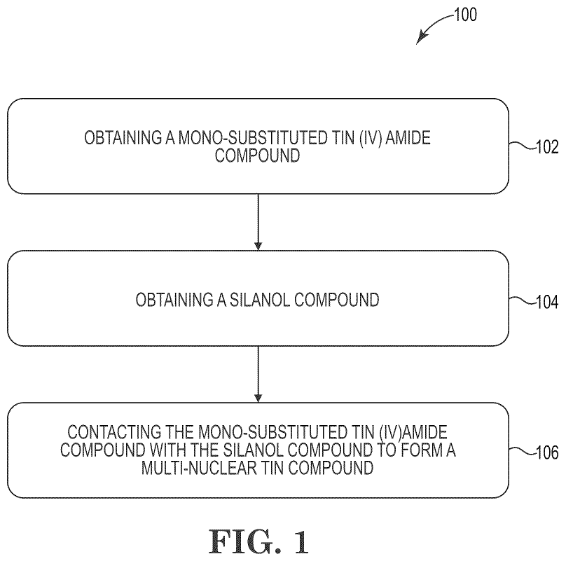

FIG. 1 is a flowchart of a method 100 for producing a multi-nuclear tin compound, according to some embodiments. As shown in FIG. 1, the method 100 for producing the multi-nuclear tin compound comprises one or more of the following steps: obtaining 102 a mono-substituted tin (IV) amide compound; obtaining 104 a silanol compound; and contacting 106 the mono-substituted tin (IV) amide compound with the silanol compound to form a multi-nuclear tin compound, such as, for example and without limitation, a mixed-ligand multi-nuclear tin compound.

At step 102, the method 100 comprises obtaining a mono-substituted tin (IV) amide compound. In some embodiments, the mono-substituted tin (IV) amide compound is a compound of the formula:

RSn(NR¹₂)₃,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof; and
R¹ is independently a hydrogen, an alkyl, a cycloalkyl, or an aryl, or each R² is bonded to each other to form a C₃-C₂₀ N-heterocycle.
some embodiments, R is at least one of—CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R is at least one of—CH₂CF₃, —CH(CF₃)₂, —CH₂F, —CH₂CH₂F, —CF₃, —CF₂CF₃, or any combination thereof. In some embodiments, R is at least one of—CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

In some embodiments, R¹ is independently at least one of a hydrogen, a methyl, an ethyl, an isopropyl, a tert-butyl, an n-butyl, a phenyl, or any combination thereof.

In some embodiments, the mono-substituted tin (IV) amide compound comprises iPrSn(N(CH₃)₂)₃.

At step 104, the method 100 comprises obtaining a silanol compound. In some embodiments, the silanol compound is a compound of the formula:

HOSiR²₃
where:
R² is independently at least one of a hydrogen, a halide, an alkyl, an alkenyl, an alkynyl, a cycloalkyl, an aryl, an aralkyl, an alkaryl, a haloalkyl, or any combination thereof.

In some embodiments, the silanol compound comprises trimethylsilanol.

In some embodiments, R is isopropyl; R¹ is methyl; and R² is methyl.

At step 106, the method 100 comprises contacting a mono-substituted tin (IV) amide compound with a silanol compound to form a multi-nuclear tin compound.

In some embodiments, the contacting comprises reacting the mono-substituted tin (IV) amide compound with the silanol compound. In some embodiments, the contacting comprises mixing the mono-substituted tin (IV) amide compound and the silanol compound. In some embodiments, the contacting comprises agitating the mono-substituted tin (IV) amide compound and the silanol compound. In some embodiments, the contacting comprises adding the mono-substituted tin (IV) amide compound and the silanol compound to a reaction vessel. In some embodiments, the contacting comprises dissolving the mono-substituted tin (IV) amide compound and the silanol compound. In some embodiments, the contacting comprises combining the mono-substituted tin (IV) amide compound and the silanol compound. In some embodiments, the contacting is performed in solution.

In some embodiments, the multi-nuclear tin compound comprises a mixed-ligand multi-nuclear tin compound. In some embodiments, the mixed-ligand multi-nuclear tin compound comprises a compound of the formula:

[R₂Sn₂(NR¹₂)ₙ(OSiR²₃)₆₋ₙ]ₓ
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
R¹ is independently a hydrogen, an alkyl, a cycloalkyl, or an aryl, or each R¹ is bonded to each other to form a C₃-C₂₀ N-heterocycle;
R² is independently at least one of a hydrogen, a halide, an alkyl, an alkenyl, an alkynyl, a cycloalkyl, an aryl, an aralkyl, an alkaryl, or a haloalkyl;
x is 1, 1.5, or 2;
n is 1 to 5.

In some embodiments, each R is the same. In some embodiments, at least two R is the same. In some embodiments, each R is different. In some embodiments, at least two R is different.

In some embodiments, each R¹ is the same. In some embodiments, at least two R¹ is the same. In some embodiments, each R¹ is different. In some embodiments, at least two R¹ is different.

In some embodiments, each R² is the same. In some embodiments, at least two R² is the same. In some embodiments, each R² is different. In some embodiments, at least two R² is different.

In some embodiments, the mixed-ligand multi-nuclear tin compound is a compound of the formula:

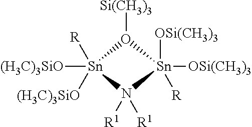

where:
R is independently at least one of —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof;
R² is independently a hydrogen, a methyl, an ethyl, an isopropyl, a tert-butyl, an n-butyl, or a phenyl.

In some embodiments, the mixed-ligand multi-nuclear tin compound is a compound of the formula:

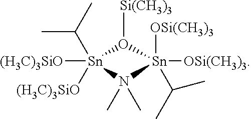

Some embodiments relate to a composition comprising a multi-nuclear tin compound. In some embodiments, the multi-nuclear tin compound comprises a mixed-ligand multi-nuclear tin compound. In some embodiments, the mixed-ligand multi-nuclear tin compound comprises a compound of the formula:

[R₂Sn₂(NR¹₂)ₙ(OSiR²₃)₆₋ₙ]ₓ
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
R¹ is independently a hydrogen, an alkyl, a cycloalkyl, or an aryl, or each R¹ is bonded to each other to form a C₃-C₂₀ N-heterocycle;
R² is independently at least one of a hydrogen, a halide, an alkyl, an alkenyl, an alkynyl, a cycloalkyl, an aryl, an aralkyl, an alkaryl, or a haloalkyl;
x is 1, 1.5, or 2;
n is 1 to 5.

In some embodiments, each R is the same. In some embodiments, at least two R is the same. In some embodiments, each R is different. In some embodiments, at least two R is different.

In some embodiments, each R¹ is the same. In some embodiments, at least two R¹ is the same. In some embodiments, each R¹ is different. In some embodiments, at least two R¹ is different.

In some embodiments, each R² is the same. In some embodiments, at least two R² is the same. In some embodiments, each R² is different. In some embodiments, at least two R² is different.

In some embodiments, the mixed-ligand multi-nuclear tin compound is a compound of the formula:

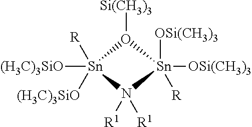

where:
R is independently at least one of —CH₂CF₃, —CH(CF₃)₂, —CH₂F, —CH₂CH₂F, —CF₃, —CF₂CF₃, —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof; and
R² is independently a hydrogen, a methyl, an ethyl, an isopropyl, a tert-butyl, an n-butyl, or a phenyl.

In some embodiments, the mixed-ligand multi-nuclear tin compound comprises a compound of the formula:

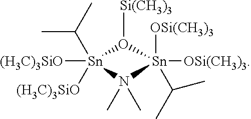

In some embodiments, a purity of the mixed-ligand multi-nuclear tin compound is at least 99.9%. In some embodiments, a purity of the mixed-ligand multi-nuclear tin compound is at least 70%, at least 75%, at least 80%, at least 85%, at least 90%, at least 91%, at least 92%, at least 93%, at least 94%, at least 95%, at least 96%, at least 97%, at least 98%, at least 99%, at least 99.9%, at least 99.99%, at least 99.999%, at least 99.9999% or greater. In some embodiments, a purity of the mixed-ligand multi-nuclear tin compound is 70% to 95%, 75% to 95%, 80% to 95%, 85% to 95%, 90% to 95%, 70% to 90%, 70% to 85%, 70% to 80%, 70% to 75%, or any range or subrange between 70% and 95%. In some embodiments, a purity of the mixed-ligand multi-nuclear tin compound is 95% to 99.9999%, 95% to 99.999%, 95% to 99.99%, 95% to 99.9%, 95% to 99%, 95% to 98%, 95% to 97%, 95% to 96%, 96% to 99.9999%, 97% to 99.9999%, 98% to 99.9999%, 99% to 99.9999%, 99.9% to 99.9999%, 99.99% to 99.9999%, 99.999% to 99.9999%, or any range or subrange between 95% to 99.9999%.

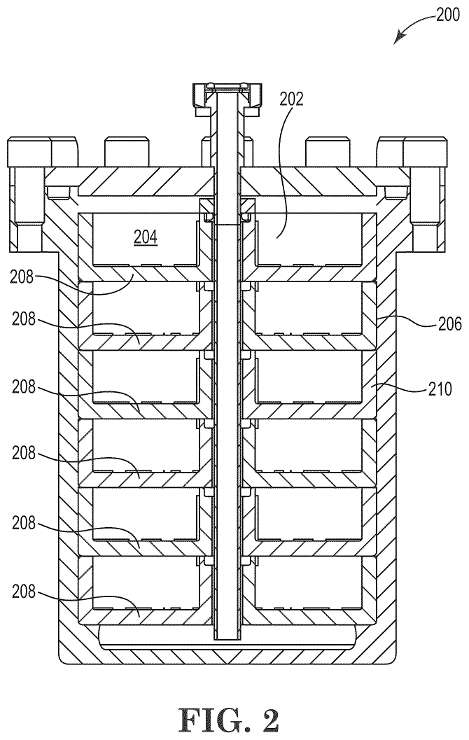

FIG. 2 depicts a schematic sectional view of a non-limiting embodiment of an ampoule 200, according to some embodiments. The ampoule 200 contains a tray assembly 202 in an inner chamber 204 of the ampoule 200. The inner chamber 204 has an inner wall surface 206. The tray assembly 202 comprises trays 208, each of which are configured to contain a vaporizable precursor. In some embodiments, the vaporizable precursor comprises any one or more of the compositions disclosed herein, including compositions comprising the multi-nuclear tin compounds. Each of the trays 208 of the tray assembly 202 comprises a portion 210 which is configured to be in contact (e.g., thermal contact, physical contact, etc.) with the inner wall surface 206 of the ampoule 200. The surface-to-surface contact of the portion 210 with the inner wall surface 206 enhances heat transfer from the ampoule 200 to each tray 208 and thus from each tray 208 to the vaporizable precursor on each tray 208. Various fluid flow paths are defined within the inner chamber 204 of the ampoule 200 such that a fluid is allowed to flow through the ampoule 200 upwards, downwards, or both. The ampoule 200 is shown having a generally cylindrical inner chamber. However, it will be appreciated that the inner chamber 204 of the ampoule may have other shapes without departing from the scope of this disclosure.

### Example 1

### Synthesis of iPr₂Sn₂ (μ-N(CH₃)₂)(OSi(CH₃)₃)₅

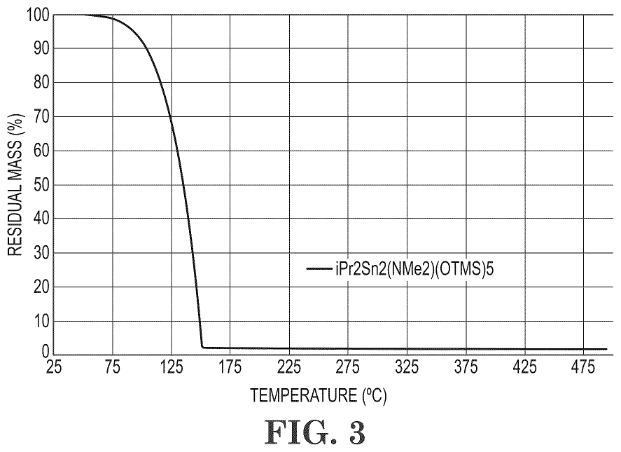

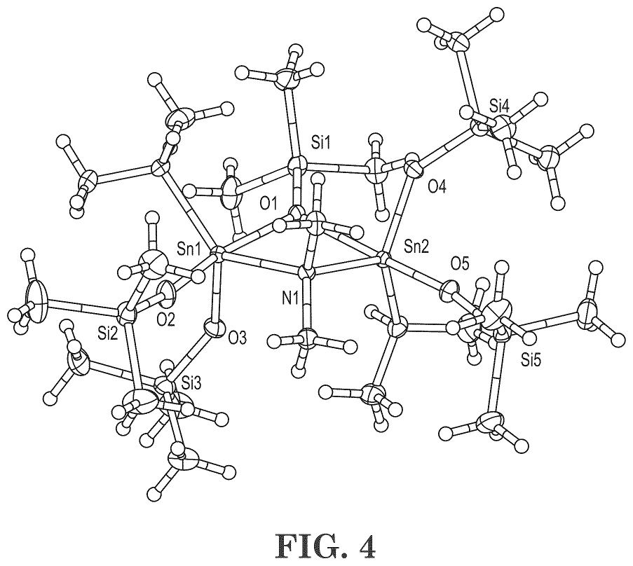

iPrSn(N(CH₃)₂)₃ (5.0 g, 17.0 mmol) (CAS #1913978-89-8) was placed in a 40 mL amber vial equipped with a magnetic stir bar and diluted with 20 mL of hexanes. The addition of a trimethylsilanol (CAS #1066-40-6) hexanes solution (4.64 g, 51.5 mmol, in 10 mL of hexanes) to the stirred tin amide solution over the course of 5 minutes resulted in an exotherm. Upon complete addition the colorless solution and was stirred for 12 hours, whereby the volatiles were removed under reduced pressure to yield the product as a brilliant white microcrystalline solid, mass: 6.68 g, yield: 91.6%. Purity: 99.96% by 1H-NMR. Melting point: (63.5° C. by DSC). Crystals suitable for X-ray crystallography were grown from the slow evaporation of a concentrated hexanes solution. ¹H{¹³C}-NMR (400 MHZ, C₆D₆, 298K): 0.28 (s, 45H); 1.22 (d, 12H); 1.74 (sept, 2H); 2.63 (s, 6H) ppm; ¹³C{¹H}-NMR (100 MHZ, C₆D₆, 298K): 3.68; 20.10; 28.11; 42.63 ppm; ¹¹⁹Sn{¹H}-NMR (149 MHZ, C₆D₆, 298K): −310.37 ppm. ²⁹Si{¹H}-NMR (79 MHZ, C₆D₆, 298K): 8.58 ppm. FIG. 3 is a thermogravimetric analysis of iPr₂Sn₂ (μ-N(CH₃)₂)(OSi(CH₃)₃)₅, according to some embodiments. FIG. 4 is a solid-state three-dimensional structural analysis of iPr₂Sn₂ (μ-N(CH₃)₂)(OSi(CH₃)₃)₅, according to some embodiments.

TABLE 1
Crystal data and structure refinement for
iPr₂Sn₂(μ-N(CH₃)₂)(μ-OSi(CH₃)₃)(OSi(CH₃)₃)₄

| Empirical formula | C23 H65 N O5 Si5 Sn2 | |
|---|---|---|
| Molecular formula | C23 H65 N O5 Si5 Sn2 | |
| Formula weight | 813.59 | |
| Temperature | 100.00 K | |
| Wavelength | 0.71073 Å | |
| Crystal system | Triclinic | |
| Space group | P-1 | |
| Unit cell dimensions | a = 9.6863(4) Å | a = 70.7610(10)°. |
| | b = 13.1774(5) Å | b = 85.4970(10)°. |
| | c = 17.3455(6) Å | g = 73.4200(10)°. |

| | |
|---|---|
| Volume | 2003.13(13) Å³ |
| Z | 2 |
| Density (calculated) | 1.349 Mg/m³ |
| Absorption coefficient | 1.423 mm⁻¹ |
| F(000) | 840 |
| Crystal size | 0.12 × 0.08 × 0.07 mm³ |
| Crystal color, habit | colorless irregular |
| Theta range for data collection | 2.504 to 26.377°. |
| Index ranges | −12 <= h <= 12, −16 <= k <= 16, −21 <= l <= 21 |
| Reflections collected | 55724 |
| Independent reflections | 8176 [R(int) = 0.0577] |
| Completeness to theta = 25.242° | 99.9% |
| Absorption correction | Semi-empirical from equivalents |
| Max. and min. transmission | 0.5475 and 0.5087 |
| Refinement method | Full-matrix least-squares on F² |
| Data / restraints / parameters | 8176 / 0 / 347 |
| Goodness-of-fit on F² | 1.023 |
| Final R indices [I > 2sigma(I)] | R1 = 0.0231, wR2 = 0.0487 |
| R indices (all data) | R1 = 0.0303, wR2 = 0.0514 |
| Extinction coefficient | 0.00066(15) |
| Largest diff. peak and hole | 0.377 and −0.333 e · Å⁻³ |

### Aspects

Various Aspects are described below. It is to be understood that any one or more of the features recited in the following Aspect(s) can be combined with any one or more other Aspect(s).

Aspect 1. A method comprising:
contacting a mono-substituted tin (IV) amide compound with a silanol compound to form a mixed-ligand multi-nuclear tin compound,
   wherein the mono-substituted tin (IV) amide compound is a compound of the formula:

RSn(NR¹₂)₃,
where:
   R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
   R¹ is independently a hydrogen, an alkyl, a cycloalkyl, or an aryl, or each R¹ is bonded to each other to form a C₃-C₂₀ N-heterocycle;
wherein the silanol compound is a compound of the formula:

HOSiR²₃
where:
   R² is independently at least one of a hydrogen, a halide, an alkyl, an alkenyl, an alkynyl, a cycloalkyl, an aryl, an aralkyl, an alkaryl, or a haloalkyl.

Aspect 2. The method according to Aspect 1, wherein R comprises at least one of —CH₂CF₃, —CH(CF₃)₂, —CH₂F, —CH₂CH₂F, —CF₃, —CF₂CF₃, or any combination thereof.

Aspect 3. The method according to any one of Aspects 1-2, wherein R comprises at least one of —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

Aspect 4. The method according to any one of Aspects 1-3, wherein R¹ is independently a hydrogen, a methyl, an ethyl, an isopropyl, a tert-butyl, an n-butyl, or a phenyl.

Aspect 5. The method according to any one of Aspects 1-4, wherein:
R is isopropyl;
R¹ is methyl; and
R² is methyl.

Aspect 6. The method according to any one of Aspects 1-5, wherein the mono-substituted tin (IV) amide compound comprises iPrSn(N(CH₃)₂)₃.

Aspect 7. The method according to Aspect 6, wherein the silanol compound comprises trimethylsilanol.

Aspect 8. The method according to any one of Aspects 1-7, wherein the mixed-ligand multi-nuclear tin compound is a compound of the formula:

[R₂Sn₂(NR¹₂)ₙ(OSiR²₃)₆₋ₙ]ₓ
where:
   R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
   R¹ is independently a hydrogen, an alkyl, a cycloalkyl, or an aryl, or each R¹ is bonded to each other to form a C₃-C₂₀ N-heterocycle;
   R² is independently at least one of a hydrogen, a halide, an alkyl, an alkenyl, an alkynyl, a cycloalkyl, an aryl, an aralkyl, an alkaryl, or a haloalkyl;
   x is 1, 1.5, or 2;
   n is 1 to 5.

Aspect 9. The method according to any one of Aspects 1-8, wherein the mixed-ligand multi-nuclear tin compound is a compound of the formula:

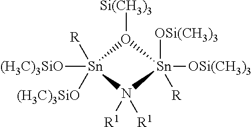

Aspect 10. The method according to any one of Aspects 1-9, wherein R comprises at least one of —CH₂CF₃, —CH(CF₃)₂, —CH₂F, —CH₂CH₂F, —CF₃, —CF₂CF₃, or any combination thereof.

Aspect 11. The method according to any one of Aspects 1-10, wherein R comprises at least one of —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

Aspect 12. The method according to any one of Aspects 1-11, wherein R² is independently a hydrogen, a methyl, an ethyl, an isopropyl, a tert-butyl, an n-butyl, or a phenyl.

Aspect 13. The method according to any one of Aspects 1-12, wherein the mixed-ligand multi-nuclear tin compound is a compound of the formula:

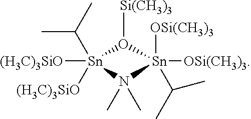

Aspect 14. A composition comprising:
a mixed-ligand multi-nuclear tin compound of the formula:

[R₂Sn₂(NR¹₂)ₙ(OSiR²₃)₆₋ₙ]ₓ
where:
   R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
   R¹ is independently a hydrogen, an alkyl, a cycloalkyl, or an aryl, or each R¹ is bonded to each other to form a C₃-C₂₀ N-heterocycle;
   R² is independently at least one of a hydrogen, a halide, an alkyl, an alkenyl, an alkynyl, a cycloalkyl, an aryl, an aralkyl, an alkaryl, or a haloalkyl;
   x is 1, 1.5, or 2;
   n is 1 to 5.

Aspect 15. The composition according to Aspect 14, wherein the mixed-ligand multi-nuclear tin compound is a compound of the formula:

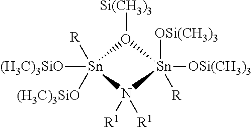

Aspect 16. The composition according to any one of Aspects 14-15, wherein R comprises at least one of —CH₂CF₃, —CH(CF₃)₂, —CH₂F, —CH₂CH₂F, —CF₃, —CF₂CF₃, or any combination thereof.

Aspect 17. The method according to any one of Aspects 14-16, wherein R comprises at least one of —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

Aspect 18. The composition according to any one of Aspects 14-17, wherein R² is independently a hydrogen, a methyl, an ethyl, an isopropyl, a tert-butyl, an n-butyl, or a phenyl.

Aspect 19. The composition according to any one of Aspects 14-18, wherein the mixed-ligand multi-nuclear tin compound comprises a compound of the formula:

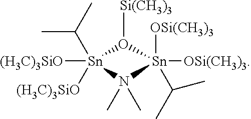

Aspect 20. The composition according to any one of Aspects 14-19, wherein a purity of the mixed-ligand multi-nuclear tin compound is at least 99.9%.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A method comprising:
contacting a mono-substituted tin (IV) amide compound with a silanol compound to form a mixed-ligand multi-nuclear tin compound,
wherein the mono-substituted tin (IV) amide compound is a compound of the formula:
RSn(NR¹₂)₃,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
R¹ is independently a hydrogen, an alkyl, a cycloalkyl, or an aryl, or each R¹ is bonded to each other to form a C₃-C₂₀ N-heterocycle;
wherein the silanol compound is a compound of the formula:
HOSiR²₃,
where:
R² is independently at least one of a hydrogen, a halide, an alkyl, an alkenyl, an alkynyl, a cycloalkyl, an aryl, an aralkyl, an alkaryl, or a haloalkyl.

2. The method of claim 1, wherein R is independently at least one of—CH₂CF₃, —CH(CF₃)₂, —CH₂F, —CH₂CH₂F, —CF₃, —CF₂CF₃, or any combination thereof.

3. The method of claim 1, wherein R is independently at least one of —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

4. The method of claim 1, wherein R¹ is independently a hydrogen, a methyl, an ethyl, an isopropyl, a tert-butyl, an n-butyl, or a phenyl.

5. The method of claim 1, wherein:
R is isopropyl;
R¹ is methyl; and
R² is methyl.

6. The method of claim 1, wherein the mono-substituted tin (IV) amide compound comprises iPrSn(N(CH₃)₂)₃.

7. The method of claim 6, wherein the silanol compound comprises trimethylsilanol.

8. The method of claim 1, wherein the mixed-ligand multi-nuclear tin compound is a compound of the formula:
[R₂Sn₂(NR¹₂)ₙ(OSiR²₃)₆₋ₙ]ₓ,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
R¹ is independently a hydrogen, an alkyl, a cycloalkyl, or an aryl, or each R¹ is bonded to each other to form a C₃-C₂₀ N-heterocycle;
R² is independently at least one of a hydrogen, a halide, an alkyl, an alkenyl, an alkynyl, a cycloalkyl, an aryl, an aralkyl, an alkaryl, or a haloalkyl;
x is 1, 1.5, or 2; and
n is 1 to 5.

9. The method of claim 1, wherein the mixed-ligand multi-nuclear tin compound is a compound of the formula:

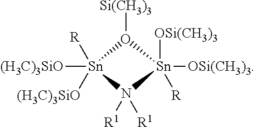

10. The method of claim 1, wherein R is independently at least one of —CH₂CF₃, —CH(CF₃)₂, —CH₂F, —CH₂CH₂F, —CF₃, —CF₂CF₃, or any combination thereof.

11. The method of claim 1, wherein R is independently at least one of —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

12. The method of claim 1, wherein R¹ is independently a hydrogen, a methyl, an ethyl, an isopropyl, a tert-butyl, an n-butyl, or a phenyl.

13. The method of claim 1, wherein the mixed-ligand multi-nuclear tin compound is a compound of the formula:

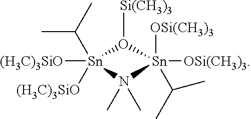

14. A composition comprising:
a mixed-ligand multi-nuclear tin compound of the formula:
[R₂Sn₂(NR¹₂)ₙ(OSiR²₃)₆₋ₙ]ₓ,
where:
R is at least one of an alkyl, an alkenyl, an alkynyl, a cycloalkyl, an aryl, a silyl, a silylalkyl, an aminoalkyl, an alkoxyalkyl, an aralkyl, a fluoroalkyl, a haloalkyl, a silylated alkoxide, an ether, an amine, a halide, an imide, a cyanate, a nitrile, an alkoxide, a carboxylate, an enolate, an ester, a cyclopentadienyl, or any combination thereof;
R¹ is independently a hydrogen, an alkyl, a cycloalkyl, or an aryl, or each R¹ is bonded to each other to form a C₃-C₂₀ N-heterocycle;
R² is independently at least one of a hydrogen, a halide, an alkyl, an alkenyl, an alkynyl, a cycloalkyl, an aryl, an aralkyl, an alkaryl, or a haloalkyl;
x is 1, 1.5, or 2; and
n is 1 to 5.

15. The composition of claim 14, wherein the mixed-ligand multi-nuclear tin compound is a compound of the formula:

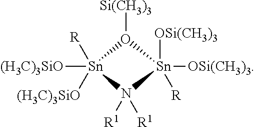

16. The composition of claim 14, wherein R is independently at least one of —CH₂CF₃, —CH(CF₃)₂, —CH₂F, —CH₂CH₂F, —CF₃, —CF₂CF₃, or any combination thereof.

17. The composition of claim 14, wherein R is independently at least one of —CH₃, —CH₂CH₃, —CH₂CH₂CH₃, —CH(CH₃)₂, —CH(CH₃) CH₂CH₃, —CH₂CH(CH₃)₂, —C(CH₃)₃, —(CH₂)₃CH₃, —C₆H₅, —CH₂ (C₆H₅), —CH═CH₂, —C≡CCH₃, —CH₂C≡CH, —CH₂C≡CCH₃, —C(CH₃)═CH₂, —HC═CHCH₃, —CH₂CH═CH₂, —CH₂N(CH₃)₂, —(CH₂)₃N(CH₃)₂, —CH₂CH₂OCH₃, —CH(CH₂)₂O, —CH₂Si(CH₃)₃, —Si(CH₃)₃, or any combination thereof.

18. The composition of claim 14, wherein R¹ is independently a hydrogen, a methyl, an ethyl, an isopropyl, a tert-butyl, an n-butyl, or a phenyl.

19. The composition of claim 14, wherein the mixed-ligand multi-nuclear tin compound comprises a compound of the formula:

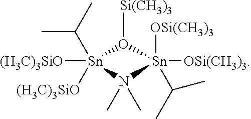

20. The composition of claim 14, wherein a purity of the mixed-ligand multi-nuclear tin compound is at least 99.9%.
